(19) United States
(12) Patent Application Publication
(10) Pub. No.: US 2023/0284530 A1
(43) Pub. Date: Sep. 7, 2023

(54) THERMOELECTRIC COOLING MODULE

(71) Applicant: Acer Incorporated, New Taipei City (TW)

(72) Inventors: Yu-Shih Wang, New Taipei City (TW); Yi-Ta Huang, New Taipei City (TW); Hung-Jen Su, New Taipei City (TW); Chih-Chun Liu, New Taipei City (TW); Cheng-Nan Ling, New Taipei City (TW); Wen-Chieh Tai, New Taipei City (TW)

(73) Assignee: Acer Incorporated, New Taipei City (TW)

(21) Appl. No.: 17/949,221

(22) Filed: Sep. 21, 2022

(30) Foreign Application Priority Data
Mar. 2, 2022 (TW) 111107523

(51) Int. Cl. H01L 35/32

(52) U.S. Cl. CPC H01L 35/32; H01L 35/16

(57) ABSTRACT

A thermoelectric cooling module including multiple P-type thermoelectric units, multiple N-type thermoelectric units, multiple electrical connecting members, and a filler is provided. Each of the electrical connecting members is electrically connected between the P-type thermoelectric unit and the N-type thermoelectric unit that are adjacent. The filler is disposed between the P-type thermoelectric unit and the N-type thermoelectric unit that are adjacent, and is also disposed at a surrounding of the P-type thermoelectric units and the N-type thermoelectric units.

### CROSS-REFERENCE TO RELATED APPLICATION

This application claims the priority benefit of Taiwan application serial no. 111107523, filed on Mar. 2, 2022. The entirety of the above-mentioned patent application is hereby incorporated by reference herein and made a part of this specification.

### BACKGROUND

### Technical Field

The disclosure relates to a thermoelectric cooling module.

### Description of Related Art

A thermoelectric material is a functional semiconductor material that may convert two different types of energy, heat and electricity, to each other without the assistance of other specific external forces or machine elements, and main modes of the thermoelectric conversion include the power generation effect and the cooling effect.

Taking the thermoelectric cooling effect as an example, a P-type semiconductor and an N-type semiconductor are connected in series, and then a direct current is applied to enable carriers (holes or electrons) therein to move in different directions, thereby forming a temperature difference.

Generally speaking, the P-type semiconductors and the N-type semiconductors are mostly arranged in a cell array. However, due to spacings or gaps between the cells, external water vapor may easily enter, thereby causing an electrical short circuit. Especially after the above temperature difference is formed, condensation is easy to occur on the cold side, which increases the possibility of water vapor entering the spacings or gaps, and even causes corrosion to the P-type semiconductors and the N-type semiconductors, seriously affecting the service lives thereof.

### SUMMARY

The disclosure provides a thermoelectric cooling module, in which a filler is added between adjacent thermoelectric units and a surrounding to form a seamless structure and effectively block infiltration of water vapor.

The thermoelectric cooling module includes multiple P-type thermoelectric units, multiple N-type thermoelectric units, multiple electrical connecting members, and a filler. Each of the electrical connecting members is electrically connected between the P-type thermoelectric unit and the N-type thermoelectric unit that are adjacent. The filler is disposed between the P-type thermoelectric unit and the N-type thermoelectric unit that are adjacent, and is disposed at a surrounding of the P-type thermoelectric units and the N-type thermoelectric units.

Based on the above, in the thermoelectric cooling module, the filler is disposed between the P-type thermoelectric unit and the N-type thermoelectric unit that are adjacent, and is also disposed at the surrounding of the P-type thermoelectric units and the N-type thermoelectric units. In this way, the filler may effectively avoid the possibility of damage to the P-type thermoelectric units and the N-type thermoelectric units due to the water vapor, thereby improving the structural strength and service life of the thermoelectric cooling module.

### BRIEF DESCRIPTION OF THE DRAWINGS

FIG. 1 is a simple schematic view of a thermoelectric cooling module according to an embodiment of the disclosure.

FIG. 2 is a partial schematic structural view of the thermoelectric cooling module of FIG. 1.

FIG. 3 is a schematic view of the thermoelectric cooling module of FIG. 2 with a filler removed.

FIGS. 4 to 6 are schematic views of part of a manufacturing process of a thermoelectric cooling module.

### DETAILED DESCRIPTION OF DISCLOSED EMBODIMENTS

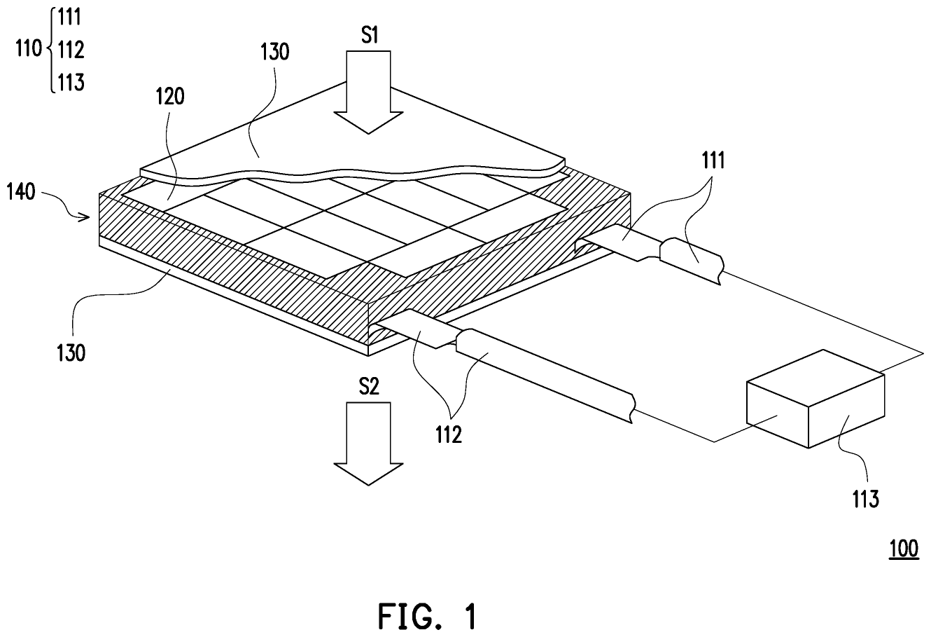

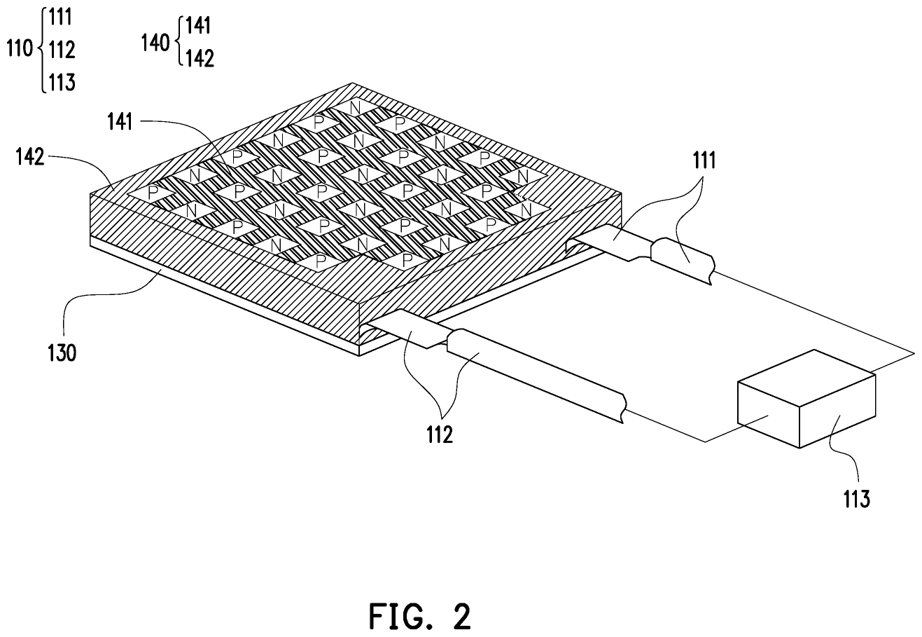

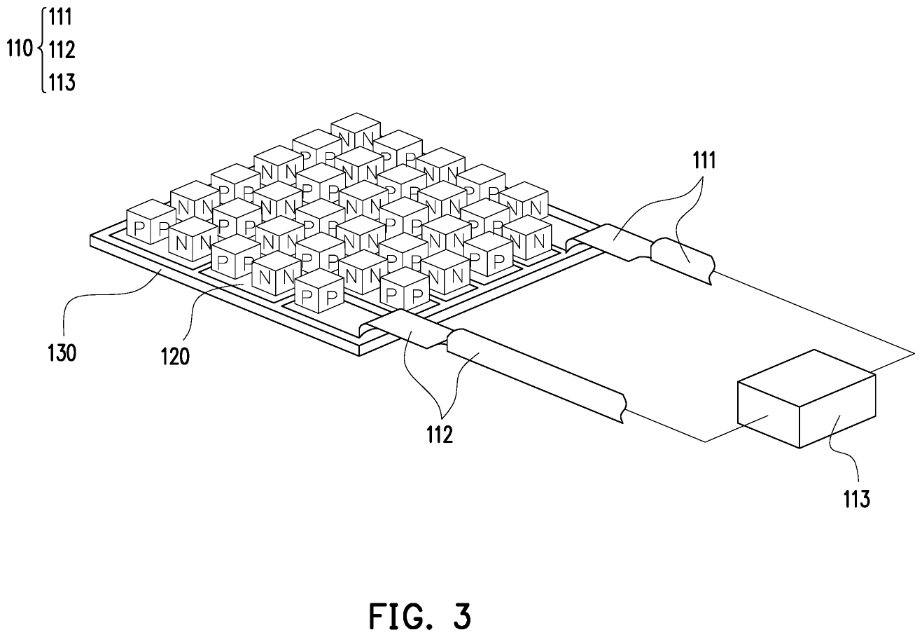

FIG. 1 is a simple schematic view of a thermoelectric cooling module according to an embodiment of the disclosure. FIG. 2 is a partial schematic structural view of the thermoelectric cooling module of FIG. 1. FIG. 3 is a schematic view of the thermoelectric cooling module of FIG. 2 with a filler removed. Referring to FIGS. 1 to 3 together, in this embodiment, a thermoelectric cooling module 100 includes multiple P-type thermoelectric units P, multiple N-type thermoelectric units N, multiple electrical connecting members 120, and a filler 140. Each of the electrical connecting members 120 is electrically connected between the P-type thermoelectric unit P and the N-type thermoelectric unit N that are adjacent. The filler 140 is disposed between the P-type thermoelectric unit P and the N-type thermoelectric unit N that are adjacent, and is also disposed at a surrounding of the P-type thermoelectric units P and the N-type thermoelectric units N.

Here, the P-type thermoelectric units P and the N-type thermoelectric units N are, for example, impurity semiconductor structures formed by bismuth telluride (Bi₂Te₃), which are electrically connected together through the electrical connecting members 120 to form an electrical couple.

Furthermore, the thermoelectric cooling module 100 in this embodiment further includes a power supply module 110 and a pair of insulating substrates 130. The insulating substrate 130 is, for example, a ceramic substrate. The P-type thermoelectric units P and the N-type thermoelectric units N stand in an array between the pair of insulating substrates 130, while the electrical connecting members 120 are also distributed on an upper layer and a lower layer in a staggered way along with the pair of insulating substrates 130. The power supply module 110 is electrically connected in series to the electrical connecting members 120, the P-type thermoelectric units P, and the N-type thermoelectric units N. When the power supply module 110 supplies power to the P-type thermoelectric units P and the N-type thermoelectric units N, the P-type thermoelectric units P and the N-type thermoelectric units N absorb heat from an external environment to be a heat absorption side S1 of the thermoelectric cooling module 100 through one of the insulating substrates 130, such as the insulating substrate 130 located on the upper layer as shown in FIG. 1. At the same time, the P-type thermoelectric units P and the N-type thermoelectric units N also release the heat to the external environment to be a heat dissipation side S2 of the thermoelectric cooling module 100 through the other of the insulating substrates 130, such as the insulating substrate 130 located on the lower layer as shown in FIG. 1.

Further, the power supply module 110 in this embodiment includes a (DC) power source 113, a first conductive line 111, and a second conductive line 112. The power source 113 is electrically connected to one of the N-type thermoelectric units N through the first conductive line 111, and the power source 113 is electrically connected to one of the P-type thermoelectric units P through the second conductive line 112, so that the power source 113, the first conductive line 111, the P-type thermoelectric units P, the N-type thermoelectric units N, the electrical connecting members 120, and the second conductive line 112 form an electrical path.

As shown in FIG. 2, in this embodiment, more importantly, the filler 140 includes a soft filling portion 141 and a hard filling portion 142. The soft filling portion 141 is located between any of the P-type thermoelectric unit P and the N-type thermoelectric unit N that are adjacent, and the hard filling portion 142 is located at the surrounding of the P-type thermoelectric units P and the N-type thermoelectric units N. Here, different types of section lines are used to facilitate identification.

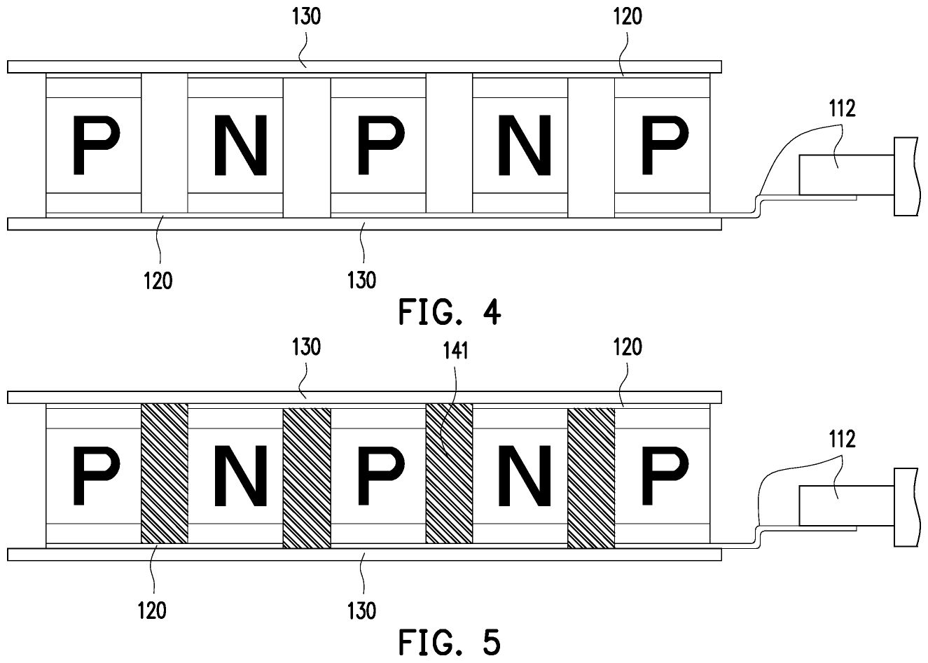

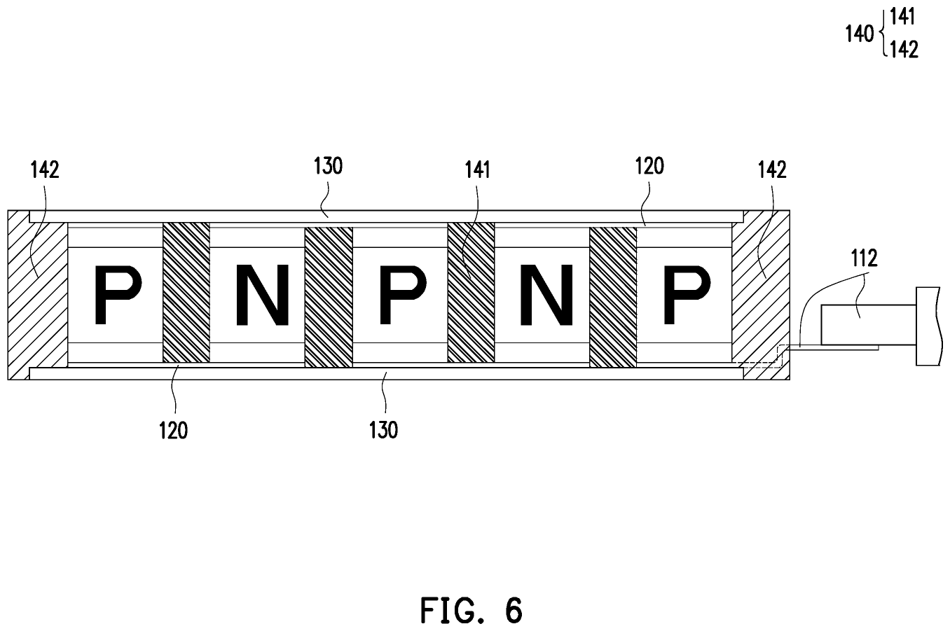

FIGS. 4 to 6 are schematic views of part of a manufacturing process of a thermoelectric cooling module. Referring to FIGS. 4 to 6 and comparing with FIG. 2, in this embodiment, a material of the soft filling portion 141 is, for example, silicon rubber, and a material of the hard filling portion 142 is, for example, plastic or high-hardness rubber. First, referring to FIGS. 4 and 5, and comparing with FIG. 2, in this embodiment, after the thermoelectric cooling module 100 is manufactured, as shown in FIG. 4 (or FIG. 3), there is a spacing (gap) between the P-type thermoelectric unit P and the N-type thermoelectric unit N that are adjacent. As mentioned above, a structural feature in this state is often damaged due to the entry of water vapor. Therefore, as shown in FIG. 4, liquid silicone rubber is first injected between any of the P-type thermoelectric unit P and the N-type thermoelectric unit N that are adjacent, so as to discharge air and the water vapor and be cured to form the above soft filling portion 141. Finally, liquid plastic or liquid rubber is injected at the surrounding of the P-type thermoelectric units P and the N-type thermoelectric units N, and is cured to form the above hard filling portion 142. Accordingly, the soft filling portion 141 may effectively remove the air and the water vapor between the adjacent thermoelectric units, and the hard filling portion 142 further forms an enclosed structure with the insulating substrate 130, so as to effectively block the connection between the thermoelectric units and the external environment, while also enabling the thermoelectric cooling module 100 to have better structural strength.

Here, an injection method of the above liquid materials is not limited, which may be appropriately adjusted according to an external structure of the thermoelectric cooling module 100. In this embodiment, the thermoelectric cooling module 100 has a rectangular parallelepiped structure. Therefore, referring to FIG. 2 or 3, first, adjacent two sides of the rectangular parallelepiped structure are used as a reference to erect the rectangular parallelepiped structure, and another two sides of the rectangular parallelepiped structure are located above. The adjacent two sides as the reference are supported and blocked by a fixture, and then the liquid silicone rubber may be smoothly injected into the rectangular parallelepiped structure through the another two sides, so as to effectively discharge the air and the water vapor inside. After the liquid silicone rubber is cured, the liquid plastic or the liquid rubber is injected along the four sides of the rectangular parallelepiped structure, that is, the surrounding. After curing, the manufacturing process of the thermoelectric cooling module 100 is completed.

Based on the above, in the embodiments of the disclosure, in the thermoelectric cooling module, the filler is disposed between the P-type thermoelectric unit and the N-type thermoelectric unit that are adjacent, and is also disposed at the surrounding of the P-type thermoelectric units and the N-type thermoelectric units. Further, the filler includes the soft filling portion and the hard filling portion. The soft filling portion may effectively discharge the water vapor out of the thermoelectric cooling module, and the hard filling portion may eliminate the connection of the P-type thermoelectric units and N-type thermoelectric units and the external environment. Accordingly, the filler may avoid the possibility of damage to the P-type thermoelectric units and the N-type thermoelectric units due to the water vapor, thereby improving the structural strength and service life of the thermoelectric cooling module.

What is claimed is:

1. A thermoelectric cooling module, comprising:
a plurality of P-type thermoelectric units;
a plurality of N-type thermoelectric units;
a plurality of electrical connecting members, wherein each of the electrical connecting members is electrically connected between the P-type thermoelectric unit and the N-type thermoelectric unit that are adjacent; and
a filler disposed between the P-type thermoelectric unit and the N-type thermoelectric unit that are adjacent, and is disposed at a surrounding of the P-type thermoelectric units and the N-type thermoelectric units.

2. The thermoelectric cooling module according to claim 1, further comprising a pair of insulating substrates, wherein the P-type thermoelectric units and the N-type thermoelectric units stand in an array between the pair of insulating substrates, and the electrical connecting members are distributed on an upper layer and a lower layer along with the pair of insulating substrates.

3. The thermoelectric cooling module according to claim 2, further comprising a power supply module electrically connected to the electrical connecting members, the P-type thermoelectric units, and the N-type thermoelectric units, wherein when the power supply module supplies power to the P-type thermoelectric units and the N-type thermoelectric units, the P-type thermoelectric units and the N-type thermoelectric units absorb heat from an external environment through one of the insulating substrates, and release the heat to the external environment through the other of the insulating substrates.

4. The thermoelectric cooling module according to claim 3, wherein the power supply module comprises a power source, a first conductive line, and a second conductive line, the power source is electrically connected to one of the N-type thermoelectric units through the first conductive line, and the power source is electrically connected to one of the P-type thermoelectric units through the second conductive line, so that the power source, the first conductive line, the N-type thermoelectric units, the P-type thermoelectric units, the electrical connecting members, and the second conductive line form an electrical path.

5. The thermoelectric cooling module according to claim 1, wherein the filler comprises a soft filling portion and a hard filling portion, wherein the soft filling portion is located between any of the P-type thermoelectric unit and the N-type thermoelectric unit that are adjacent, and the hard filling portion is located at the surrounding of the P-type thermoelectric units and the N-type thermoelectric units.

6. The thermoelectric cooling module according to claim 5, wherein a material of the soft filling portion is silicon rubber.

7. The thermoelectric cooling module according to claim 5, wherein a material of the hard filling portion is plastic or high-hardness rubber.

8. The thermoelectric cooling module according to claim 5, wherein a first liquid material is first injected, by the filler, between any of the P-type thermoelectric unit and the N-type thermoelectric unit that are adjacent to discharge air and water vapor and be cured to form the soft filling portion, and a second liquid material is injected at the surrounding of the P-type thermoelectric units and the N-type thermoelectric units, and is cured to form the hard filling portion.
